(19) United States
(12) Patent Application Publication
(10) Pub. No.: US 2026/0005198 A1
(43) Pub. Date: Jan. 1, 2026

(54) SEMICONDUCTOR DEVICE INCLUDING PAIRED MEMORY DEVICES

(71) Applicant: Sandisk Technologies, Inc., Milpitas, CA (US)

(72) Inventor: Nagesh Vodrahalli, Los Altos, CA (US)

(73) Assignee: Sandisk Technologies, Inc., Milpitas, CA (US)

(21) Appl. No.: 18/756,374

(22) Filed: Jun. 27, 2024

(51) Int. Cl. H01L 25/065; H10B 80/00

(52) U.S. Cl. CPC H01L 25/0657; H10B 80/00; H01L 2225/06513

(57) ABSTRACT

A semiconductor device includes one or more paired CMOS bonded array (CBA) dies. Each paired CBA memory die includes first and second CBA memory dies. Each CBA memory die includes a first semiconductor die having a memory array formed in a silicon substrate and a second semiconductor die having CMOS logic circuits formed in a silicon substrate. The paired CBA memory dies may be affixed to each other face-to-face; that is, with their active surfaces facing each other. In such a configuration, the disparate coefficients of thermal expansion of the device layers and silicon substrate balance each other to prevent warping of the paired CBA memory die.

### BACKGROUND

The strong growth in demand for portable consumer electronics is driving the need for high-capacity storage devices. Non-volatile semiconductor memory devices, such as flash memory storage cards, are widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs, cellular telephones and solid state drives (SSDs).

Recently, ultra high density memory devices have been proposed using a 3D stacked memory structure having strings of memory cells formed into layers. One such storage device is sometimes referred to as a Bit Cost Scalable (BiCS) architecture. BiCS and other NAND memory devices are fabricated in a wafer which includes the memory device layer formed in a substrate base, such as silicon. The wafer is diced into individual semiconductor dies, which are then stacked, electrically connected and encapsulated to form a competed semiconductor memory package.

Given the ever-present drive to provide greater storage capacity in a smaller form factor, semiconductor devices are made as thin as possible, currently about 36 microns (μm). Mechanical factors such as die warping, chipping and/or cracking during semiconductor package fabrication are proving a barrier to further reduction in thickness of semiconductor dies. For example, heating of the semiconductor dies during package fabrication causes the dies to warp given the different coefficients of thermal expansion between the memory device layers and silicon substrate. This warping becomes significant at thicknesses below 36 μm, to the point where the dies may crack, or wire bonds separate, when stacked and/or encapsulated. Moreover, when dies are thinned, for example to below 36 μm, die chipping or cracking when handled during fabrication also becomes a significant problem preventing further reductions in the thicknesses of semiconductor dies.

### DESCRIPTION OF THE DRAWINGS

FIG. 1 is a flowchart for forming a CBA memory device according to embodiments of the present technology.

FIG. 2 is a top view of a first semiconductor wafer, and a first semiconductor die therefrom, according to embodiments of the present technology.

FIG. 3 is a top view of a second semiconductor wafer, and a second semiconductor die therefrom, according to embodiments of the present technology.

FIG. 4 is a cross-sectional edge view of a first semiconductor of the first wafer die according to embodiments of the present technology.

FIG. 5 is a cross-sectional edge view of a second semiconductor die of the second wafer according to embodiments of the present technology.

FIG. 6 is a cross-sectional edge view of the first and second wafers being joined to form a CBA memory wafer according to embodiments of the present technology.

FIG. 7 is a flowchart for forming a paired CBA memory device from first and second CBA memory wafers according to embodiments of the present technology.

FIG. 8 is a schematic perspective view of first and second CBA memory wafers positioned for being joined together according to embodiments of the present technology.

FIG. 9 is a cross-sectional edge view of first and second CBA memory wafers positioned for being joined together according to embodiments of the present technology.

FIG. 10 is a cross-sectional edge view of first and second CBA memory wafers joined together to form a paired CBA memory wafer according to embodiments of the present technology.

FIG. 11 is a cross-sectional edge view of a paired CBA memory wafer with an inactive surface of one of the CBA wafers having been thinned according to embodiments of the present technology.

FIG. 12 is a cross-sectional edge view of the paired CBA memory wafer of FIG. 11 with bump pads having been formed on the thinned surface according to embodiments of the present technology.

FIG. 13 is a cross-sectional edge view of a paired CBA memory wafer with an inactive surface of the other CBA wafer having been thinned according to embodiments of the present technology.

FIG. 14 is a cross-sectional edge view of the paired CBA memory wafer of FIG. 13 with bump pads having been formed on the thinned surface according to embodiments of the present technology.

FIG. 15 is a cross-sectional edge view of a plurality of paired CBA memory dies stacked on a substrate according to embodiments of the present technology.

FIG. 16 is a cross-sectional edge view of a finished paired CBA memory die according to embodiments of the present technology.

FIG. 17 is a graph of die warpage vs. die thickness.

FIGS. 18 and 19 are cross-sectional edge views of NAND stacks according to alternative embodiments of the present technology.

### DETAILED DESCRIPTION

The present technology will now be described with reference to the figures, which in embodiments, relate to a semiconductor device including one or more paired CMOS bonded array (CBA) dies. Each paired CBA memory die includes first and second CBA memory dies. Each CBA memory die includes a first semiconductor die having a memory array formed in a silicon substrate and a second semiconductor die having CMOS logic circuits formed in a silicon substrate. The paired CBA memory dies may be affixed to each other face-to-face; that is, with their active surfaces facing each other. In such a configuration, the disparate coefficients of thermal expansion of the device layers and silicon substrate balance each other to prevent warping of the paired memory die. This ability to prevent warping in part enables a high bandwidth, high storage capacity memory device a where the thicknesses of the dies in the paired memory die may be thinner than was previously achievable. Additionally, the overall thickness of the paired memory die may be sufficient to avoid chipping or cracking during handling of the paired memory die during fabrication.

Economies of scale may be achieved by fabricating a number of paired memory dies simultaneously at the wafer level. In particular, a pair of CBA memory wafers may be formed with aligned (mirror image) bond pads. Thereafter the wafers may be physically and electrically coupled to each other, for example in a Cu—Cu bonding process or a hybrid bonding process. The paired CBA memory wafer may then be diced into individual paired CBA memory dies, which dies may then be stacked into a completed semiconductor device.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is +0.15 mm, or alternatively, +2.5% of a given dimension.

For purposes of this disclosure, a physical or electrical connection may be a direct connection or an indirect connection (e.g., via one or more other parts). In some cases, when a first element is referred to as being connected, affixed, mounted or coupled to a second element (either physically or electrically), the first and second elements may be directly connected, affixed, mounted or coupled to each other or indirectly connected, affixed, mounted or coupled to each other (either physically or electrically). When a first element is referred to as being directly connected, affixed, mounted or coupled to a second element, then there are no intervening elements between the first and second elements (other than possibly an adhesive or melted metal used to connect, affix, mount or couple the first and second elements).

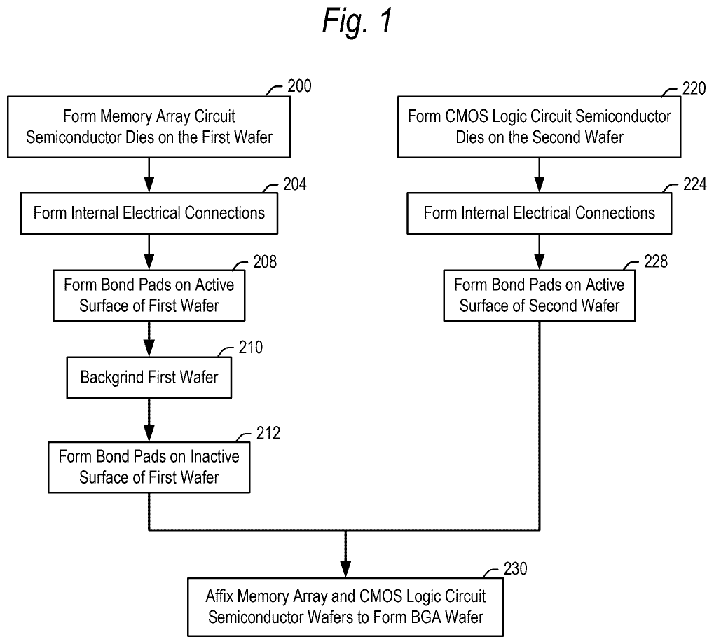

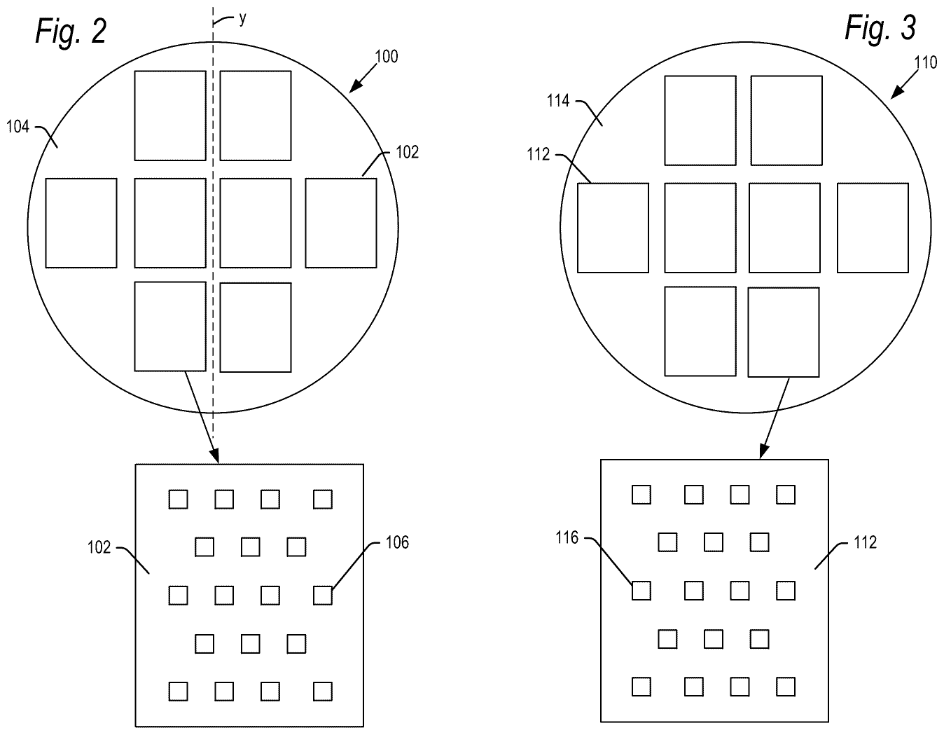

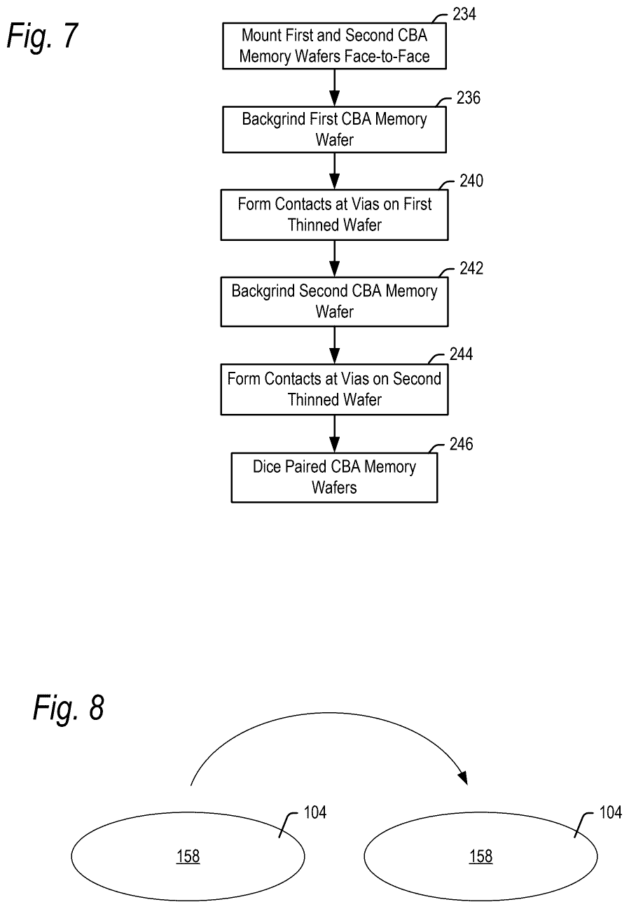

An embodiment of the present technology will now be explained with reference to the flowchart of FIGS. 1 and 7, and the views of FIGS. 2-6 and 8-19. In step 200, a first semiconductor wafer 100 may be processed into a number of first semiconductor dies 102, such as for example memory array semiconductor dies, as shown in FIG. 2. The first semiconductor wafer 100 may start as an ingot of wafer material which may be monocrystalline silicon grown according to either a Czochralski (CZ) or floating zone (FZ) process. However, first wafer 100 may be formed of other materials and by other processes in further embodiments.

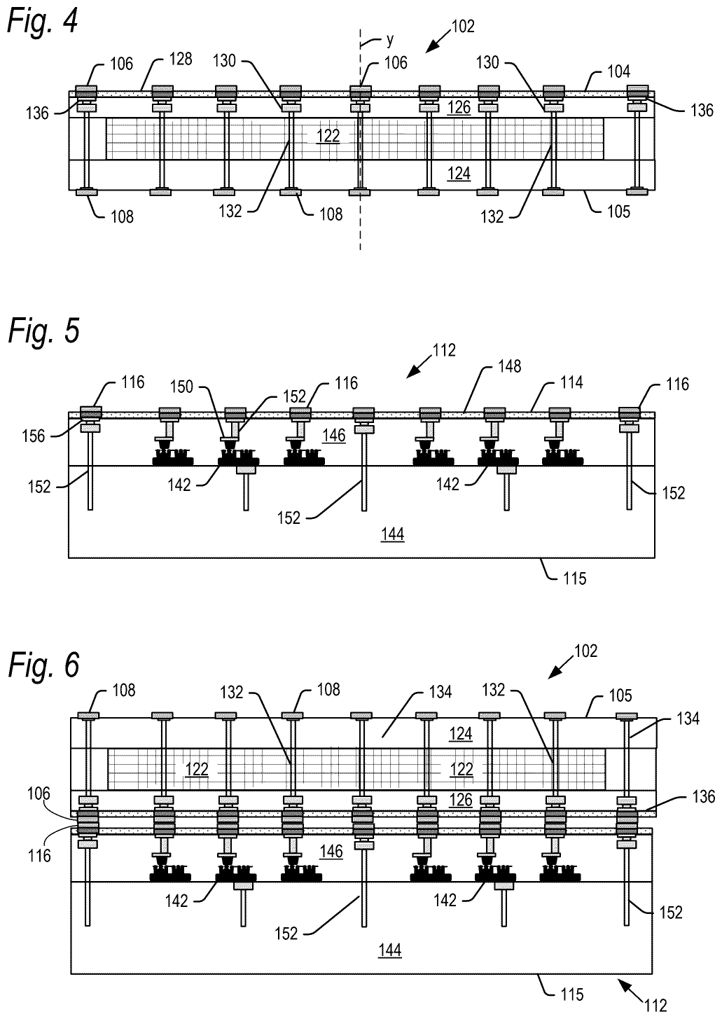

The semiconductor wafer 100 may be cut from the ingot and polished on both the first major planar surface 104, and second major planar surface 105 (FIG. 4) opposite surface 104, to provide smooth surfaces. The first major surface 104 may undergo various processing steps to divide the wafer 100 into the respective first semiconductor dies 102, and to form integrated circuits of the respective first semiconductor dies 102 on and/or in the first major surface 104. FIG. 2 further shows detail of a single semiconductor die 102 including a pattern of micro-bump pads 106 as explained below.

The processing of wafer 100 in step 200 may include the formation of integrated circuit memory cell array 122 formed in a dielectric substrate including layers 124 and 126 as shown in the cross-sectional edge view of FIG. 4. A reticle may be used to transfer an integrated circuit pattern for each semiconductor die 102 in a photolithography process. The patterned wafer can then undergo various processes such as etching, ion implantation, and deposition to create the actual semiconductor components and interconnections needed to build the integrated circuits of a semiconductor die 102. In embodiments, the integrated circuits may be a memory cell array 122 formed as a 3D stacked memory structure having strings of memory cells formed into layers. However, it is understood that the first semiconductor die 102 may be processed to include integrated circuits other than a 3D stacked memory structure. A passivation layer 128 may be formed on top of the upper dielectric film layer 126.

After formation of the memory cell array 122, internal electrical connections may be formed within the first semiconductor die 102 in step 204. The internal electrical connections may include multiple layers of metal interconnects 130 and vias 132 formed sequentially through layers of the dielectric film 126. As is known in the art, the metal interconnects 130, vias 132 and dielectric film layers 126 may be formed for example by damascene processes a layer at a time using photolithographic and thin-film deposition processes. The photolithographic processes may include for example pattern definition, plasma, chemical or dry etching and polishing. The thin-film deposition processes may include for example sputtering and/or chemical vapor deposition. The metal interconnects 130 may be formed of a variety of electrically conductive metals including for example copper and copper alloys as is known in the art, and the vias 132 may be lined and/or filled with a variety of electrically conductive metals including for example tungsten, copper and copper alloys as is known in the art. As seen for example in FIG. 4, the metal interconnects 130 and vias 132 may be formed to and through the memory cell array 122 to carry signals to and from the memory cell array 122.

In step 208, micro-bump pads 106 may be formed on the first (active) major planar surface 104 of the first semiconductor dies 102. As shown in FIGS. 2 and 4, these bump pads may be formed on top of vias 132 and may be used to transfer signals to and from the semiconductor die 102. The bump pads may be etched into the passivation layer 128, and each bump pad 106 may be formed over a liner 136. As is known in the art, the bump pads 106 may be formed for example of copper, aluminum and alloys thereof, and the liner 136 may be formed for example of a titanium/titanium nitride stack such as for example Ti/TiN/Ti, though these materials may vary in further embodiments. The bump pads 106 and liner 136 may be applied by vapor deposition and/or plating techniques. The integrated circuit memory arrays 122 may be electrically connected to the bump pads 106 by the metal interconnects 130 and vias 132.

In step 210, the first (active) surface 104 of the wafer 100 may be supported on a temporary carrier (not shown) and the second (inactive) surface 105 may be thinned in a backgrind process to a final thickness of wafer 100 (shown in FIG. 4). The thinning of the wafer may expose vias 132 at the second surface 105. Thereafter, in step 212, bond pads 108 may be formed on the inactive surface 105 as shown for example in FIG. 4.

FIG. 2 shows semiconductor dies 102 on wafer 100, and bump pads 106 in a pattern on one of the semiconductor dies 102. The number of first semiconductor dies 102 shown on wafer 100 in FIG. 2 is for illustrative purposes, and wafer 100 may include more or less first semiconductor dies 102 than are shown in further embodiments. Similarly, the pattern of bump pads 106, 108 as well as the number of bump pads 106, 108 on the first semiconductor die 102 shown in FIG. 4 are shown for illustrative purposes. Each first die 102 may include more bump pads 106 and/or 108 than are shown in further embodiments, and may include various other patterns and densities of bump pads 106 and/or 108.

Before, after or in parallel with the formation of the first semiconductor dies on wafer 100, a second semiconductor wafer 110 may be processed into a number of second semiconductor dies 112, such as for example CMOS logic circuit dies, in step 220 as shown in FIG. 3. The semiconductor wafer 110 may start as an ingot of monocrystalline silicon grown according to either a CZ, FZ or other process. The second semiconductor wafer 110 may be cut and polished on both the first major surface 114, and second major surface 115 (FIG. 5) opposite surface 114, to provide smooth surfaces. The first major surface 114 may undergo various processing steps to divide the second wafer 110 into the respective second semiconductor dies 112, and to form integrated circuits of the respective second semiconductor dies 112 on and/or in the first major surface 114. FIG. 3 further shows detail of a single semiconductor die 112 including a pattern of micro-bump pads 116 as explained below.

In one embodiment, the second semiconductor dies 112 may be processed to include integrated circuits 142 formed in a dielectric substrate including layers 144 and 146 as shown in the cross-sectional edge view of FIG. 5. Integrated circuits 142 may be configured as logic circuits to control read/write operations for one or more integrated memory cell arrays 122. The logic circuits may be fabricated using CMOS technology, though the logic circuits may be fabricated using other technologies in further embodiments. The second semiconductor dies 112 may include other and/or additional integrated circuits in further embodiments as explained below. A passivation layer 148 may be formed on top of the upper dielectric film layer 146.

After formation of the CMOS logic circuits 142, internal electrical connections may be formed within the second semiconductor die 112 in step 224. The internal electrical connections may include multiple layers of metal interconnects 150 and vias 152 formed sequentially through layers of the dielectric film 146. The metal interconnects 150, vias 152 and dielectric film layers 146 may be formed in the same manner as interconnects 130, vias 132 and dielectric film layer 126 described above for dies 102.

As seen for example in FIG. 5, the metal interconnects 150 and vias 152 may be connected to the CMOS logic circuits 142 to carry signals to and from the logic circuits 142. In step 228, micro-bump pads 116 may be formed on the major planar surface 114 of the second semiconductor dies 112. As shown in FIGS. 3 and 5, these bump pads may be on top of vias 152. As is also explained below, the bump pads 116 are provided for transferring signals to and from the semiconductor die 112. The bump pads may be etched into the passivation layer 148, and may include liners 156. Bump pads 116 and liners 156 may be formed in the same manner as bump pads 106 and liners 136 described above. The CMOS logic circuits 142 may be electrically connected to the bump pads 116 by the metal interconnects 150 and vias 152.

FIG. 3 shows semiconductor dies 112 on wafer 110, and bump pads 116 in a pattern on one of the semiconductor dies 112. The number of second semiconductor dies 112 shown on wafer 110 in FIG. 3 is for illustrative purposes, and wafer 110 may include more or less second semiconductor dies 112 than are shown in further embodiments. Similarly, the pattern of bump pads 116, as well as the number of bump pads 116, on the second semiconductor die 112 are shown for illustrative purposes. Each second die 112 may include more bump pads 116 than are shown in further embodiments, and may include various other patterns and densities of bump pads 116.

Once the fabrication of first and second semiconductor dies 102 and 112 is complete, the first and second semiconductor wafers 100 and 110 may be affixed to each other in step 230 so that the respective memory dies 102 are bonded to the CMOS logic circuit dies 112. The bonded wafers 100, 110 are referred to herein as CBA memory wafers 158, and each pair of bonded dies 102, 112 are referred to herein as a CBA memory die 160. An example of the completed CBA memory die 160 is shown for example in the cross-sectional edge view of FIG. 6. To bond the dies 102, 112, the first semiconductor wafer 100 may be flipped over (relative to the view of FIG. 4), and bump pads 106 and 116 of the respective dies 102 and 112 may be physically and electrically coupled to each other. As shown and noted, the number and pattern of bump pads 106 may match the number and pattern of bump pads 116 so that the pads align with each other when the dies 102, 112 are coupled together. In embodiments where the number and pattern of bump pads 106, 116 are not symmetrical about a central vertical axis through the dies, the number and pattern of bump pads 106 may be the mirror image of the number and pattern of bump pads 116 so that the pads 106, 116 align when die 102 is flipped over.

The first and second semiconductor dies 102, 112 in the CBA memory die 160 may be bonded to each other by initially aligning the bump pads 106 and 116 on the respective dies 102, 112 with each other. Thereafter, the bump pads 106, 116 may be bonded together by any of a variety of bonding techniques, depending in part on bump pad size and bump pad spacing (i.e., bump pad pitch). These bonding techniques include for example Cu—Cu bonding, oxide-to-oxide bonding and hybrid bonding. The bump pad size and pitch may in turn be dictated by the number of electrical interconnections required for the CBA memory die.

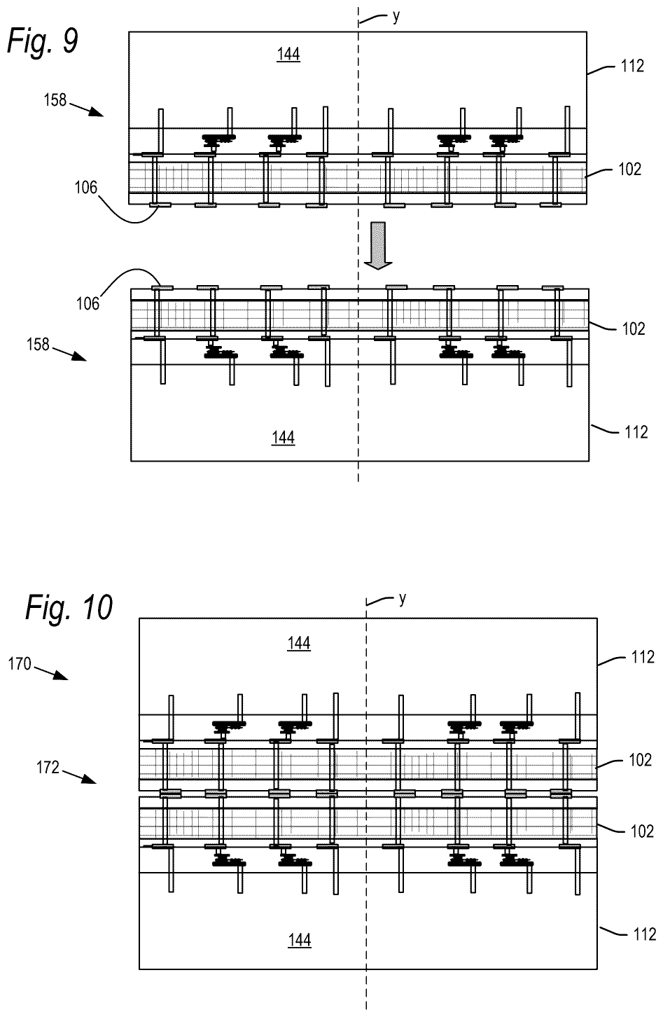

The CBA memory dies 160 from CBA memory wafer 158 may be used in a memory device but, as noted in the Background section, they may be subject to warpage when mounted in the device and/or breaking or chipping when handled. In accordance with aspects of the present technology, two such CBA memory wafers 158 may be bonded together face-to-face to solve the aforementioned problems. The flowchart of FIG. 7 shows the face-to-face bonding and processing of a pair of CBA memory wafers 158 in more detail. In step 234, the active surfaces 104 of first and second CBA memory wafers 158 may be bonded to each other face-to-face as indicated in FIG. 8. FIGS. 9 and 10 show further details of this bonding on the die level.

As shown, one of the CBA memory wafer 158 may be flipped over and positioned on top of the second CBA memory wafer 158 so that the bump pads 106 one each of the respective CBA dies 160 align with each other. This may be accomplished by ensuring that the memory dies 102 on wafer 100 are symmetrical about a y-axis shown in FIG. 2, and that the bump pads 106 on each memory die 102 are also symmetrical about a y-axis as shown in FIGS. 9 and 10. Alternatively, where the bump pads are not symmetrical about such a y-axis, a redistribution layer (RDL) may be added to the dies 102 on one of the CBA memory wafers 158 prior to their being joined to ensure that the respective pads of each of the dies within the two CBA memory wafers 158 align when the wafers are flipped over and brought together.

Once brought together, the bump pads 106 of the respective CBA memory wafers 158 may be physically bonded to each other as by Cu—Cu bonding, oxide-to-oxide bonding and hybrid bonding. Other wafer-to-wafer bonding techniques are possible. Such further techniques include various dielectric-to-dielectric bonding techniques including oxide-to-oxide bonding, silicon-to-silicon bonding, and silicon-to-silicon dioxide bonding. The two joined CBA memory wafer 158 are referred to herein as the paired CBA wafers 170. The individual dies, joined face-to-face in the paired CBA wafers are referred to herein as paired CBA dies 172.

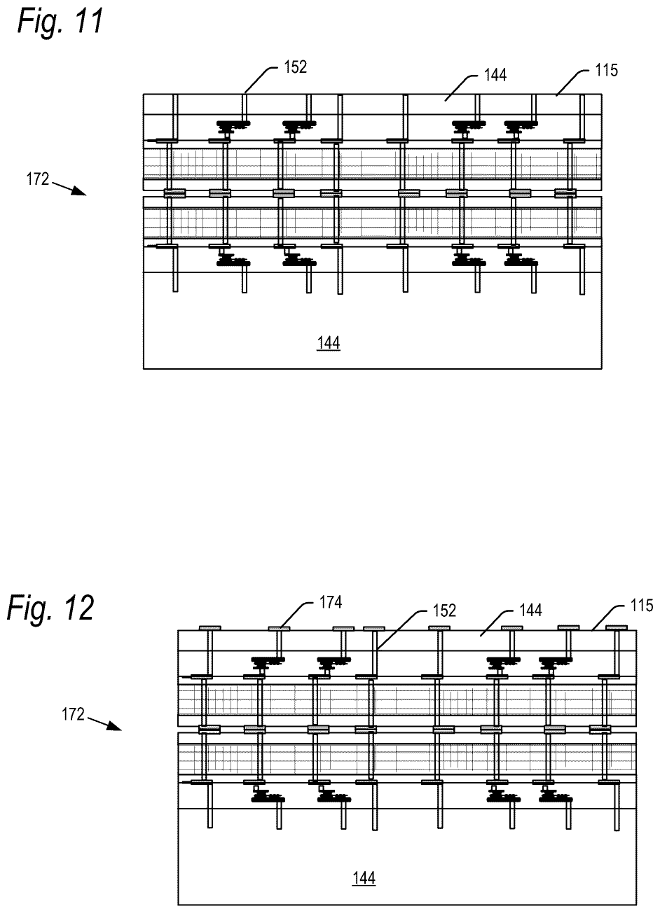

Once the CBA wafers 158 are bonded to each other, one of the CBA memory wafers 158 (e.g., the top CBA wafer) may undergo a backgrind process in step 236 to thin the wafer 110 of the first CBA memory wafer 158, for example from 760 μm to a final thickness which may range from 10 μm to 36 μm. This structure is shown in FIG. 11. It is understood that the final thickness of the thinned wafer 110 may be larger or smaller than that range in further embodiments. The backgrind process in step 236 may expose the vias 152 to the major planar surface 115 of the top CBA memory wafer 158. In step 240, bond pads 174 may then be formed over the vias 152 at the major surface 115 as shown in FIG. 12. The pattern of vias 152, and bond pads 174 thereon, are shown by way of example only and may vary in further embodiments.

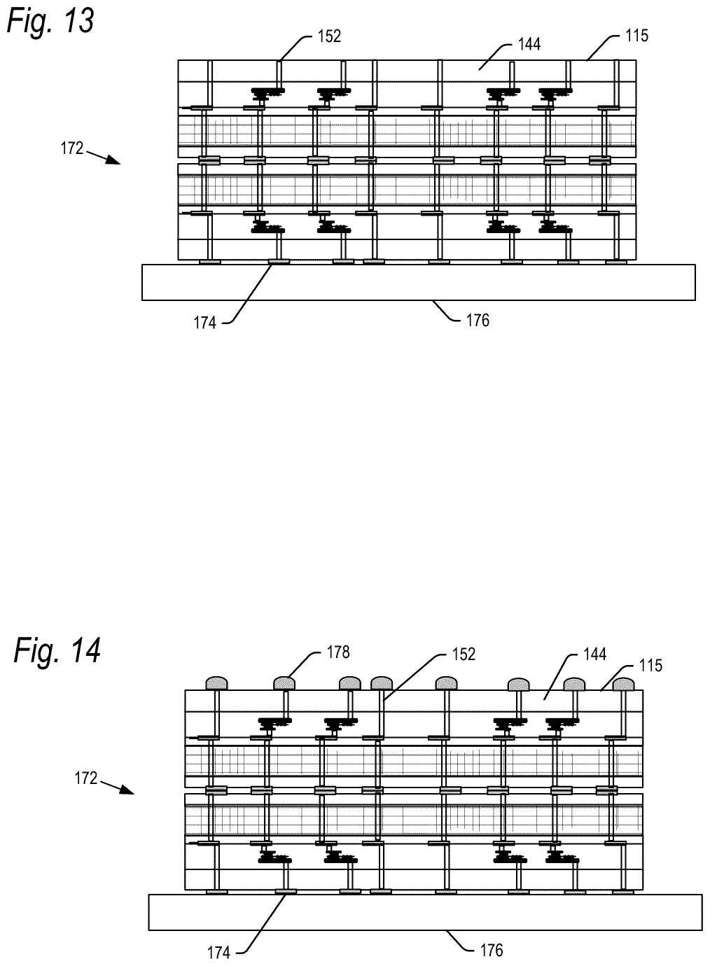

In step 242, the pair CBA wafers may be flipped over, and the major surface 115 including bond pads 174 may be temporarily affixed to a backgrind tape 176 so that the substrate 144 of the wafer 110 in the second CBA memory wafer 158 may undergo a backgrind process as shown in FIG. 13. The backgrind process thins the wafer 110 of the second CBA memory wafer, for example from 760 μm to a final thickness which may range from 10 μm to 36 μm. It is understood that the final thickness of the thinned wafer 110 may be larger or smaller than that range in further embodiments. The backgrind process in step 242 may expose the vias 152 to the major planar surface 115 of the second CBA memory wafer 158. In step 244, bump pads 178 may then be formed over the vias 152 at the major surface 115 as shown in FIG. 14. The pattern of vias 152, and bond pads 178 thereon, are shown by way of example only and may vary in further embodiments.

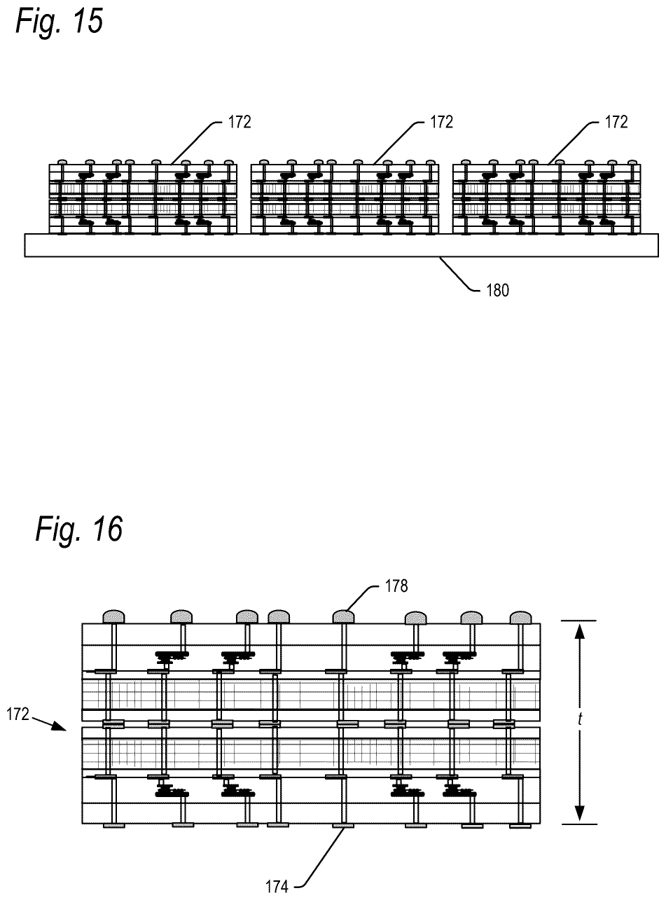

Although FIGS. 11-14 show individual paired CBA semiconductor dies 172 for simplicity, at the stage of fabrication, the dies 172 are still part of their respective paired CBA wafers 170. After the backgrind step 242 and bump pad step 244, the backgrind tape 176 may be removed, and the bottom surface 115 of the CBA wafers 170 including bond pads 174 may be supported on a dicing tape 180 as shown in FIG. 15. Thereafter, in a step 246, the paired CBA memory wafers 170 may be diced to form individual paired CBA memory dies 172. Each of these paired CBA memory dies 172 include first and second CBA memory dies 154 mounted to each other face-to-face.

The paired CBA memory wafers 170 may be diced into individual paired CBA memory dies 172 using for example stealth laser dicing. Saw blades and other traditional methods may be used in further embodiments. After dicing, the dicing tape 180 may be spread apart to facilitate picking of the paired CBA memory dies from the dicing tape by a pick and place robot (not shown).

FIG. 16 shows a completed paired CBA memory die 172 according to an embodiment of the present technology. In one embodiment, the memory die 172 may have a total thickness, t, of approximately 50 μm to 100 μm. For example, each of the CBA memory dies 154 in die 172 may have a thickness of 36 μm, resulting in a thickness, t, of about 72 μm. The thickness of the paired CBA memory die 172 may be greater or lesser than this range in further embodiments.

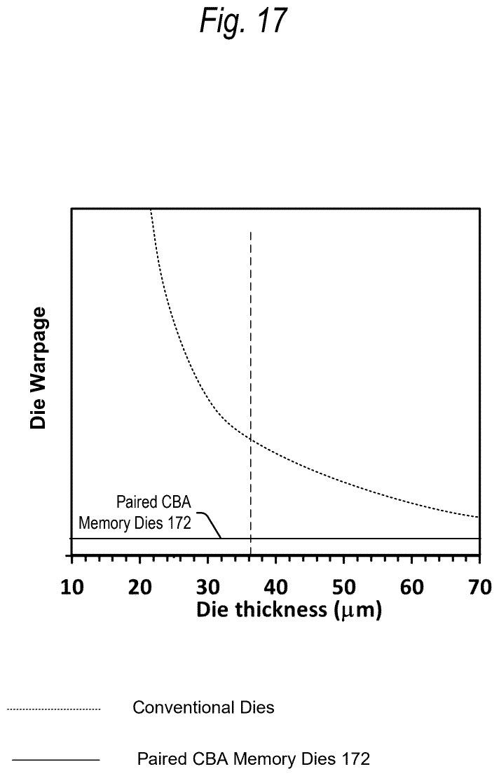

As noted in the Background section, warping of semiconductor dies becomes a significant problem as semiconductor dies get thinner due to thermal mismatch of the memory array and substrate. FIG. 17 is a graph of die warpage versus die thickness for a conventional BiCS memory device where the memory array has a thickness of about 16 to 17 μm. As this dimension does not change without reducing storage capacity, any reduction in the thickness of a semiconductor die at present may more likely come from reducing a thickness of the substrate layer. As seen in the graph of FIG. 17, for a semiconductor die of 36 μm (vertical dashed line), the warpage is high, but dies with such warpage can be packaged generally without cracking, and are typically commercially feasible. However, as seen in the graph, warpage nonlinearly increases with further decreases in die thicknesses (i.e., further decreases in substrate thickness). Such warpage would generally result in cracking of the dies when handled, stacked or encapsulated.

In accordance with aspects of the present technology, given the face-to-face mounting of the respective CBA memory wafers 160 with the active surfaces of the respective wafers face each other, the disparate coefficients of thermal expansion balance each other out, as does the strain otherwise resulting from materials having different thermal coefficients. As a result of this balance, warping of the paired CBA memory dies 172 is significantly or completely removed, as shown by the solid horizontal line in FIG. 17. This provides the advantage that the individual semiconductor dies 102, 112 to be made thinner than was feasible in the prior art.

Another advantage of pairing the CBA memory wafers together before dicing is that there is a smaller chance of the dies chipping or breaking during assembly into a device. This is true for two reasons. First, given their greater thickness, the dies are sturdier and able to withstand the stresses that occur during assembly, such as for example during encapsulation. Second, the dies are handled less. For example, to create a sixteen die conventional device, it was necessary to handle sixteen different semiconductor dies. However, as these dies are paired in the present technology, only eight such die pairs are handled.

A still further advantage of devices formed from the paired CBA memory dies 172 is improved thermal conductivity. In particular, a device formed from a number of dies, for example eight, will have gaps between each of the dies in the stack. These gaps are not thermally conductive so it is desirable to minimize the number of gaps. Using the paired CBA memory dies 172, a device can include the same number of dies, for example eight, with half of the gaps between the dies. This is so because there are no gaps between the first and second CBA memory dies in each paired CBA memory die 172. This improves the ability of such dies to conduct the heat away from each of the paired CBA dies in the stack.

High frequency memory systems make use of a high speed, specialized processor such as a graphics processor or AI processing core. These processors require high speed, large capacity memories nearby. It is known to address these memory needs with a so-called high bandwidth memory, or HBM. HBMs typically include a stack of memory dies, such as for example non-volatile memory dies, that are physically and electrically interconnected by through silicon vias. This arrangement provides a high density and high storage capacity. They typically employ a wide bus interface ranging from 1024 to 4096 bits for high data transfer rates.

In accordance with the present technology, use of paired CBA memory dies in a NAND stack effectively doubles the storage capacity. For example, where traditional designs may include eight semiconductor dies in the stack, a NAND stack built from the paired CBA memory dies of the present technology may include eight CBA die pairs, or sixteen CBA dies total, in the same form factor which previously used eight (thicker) dies.

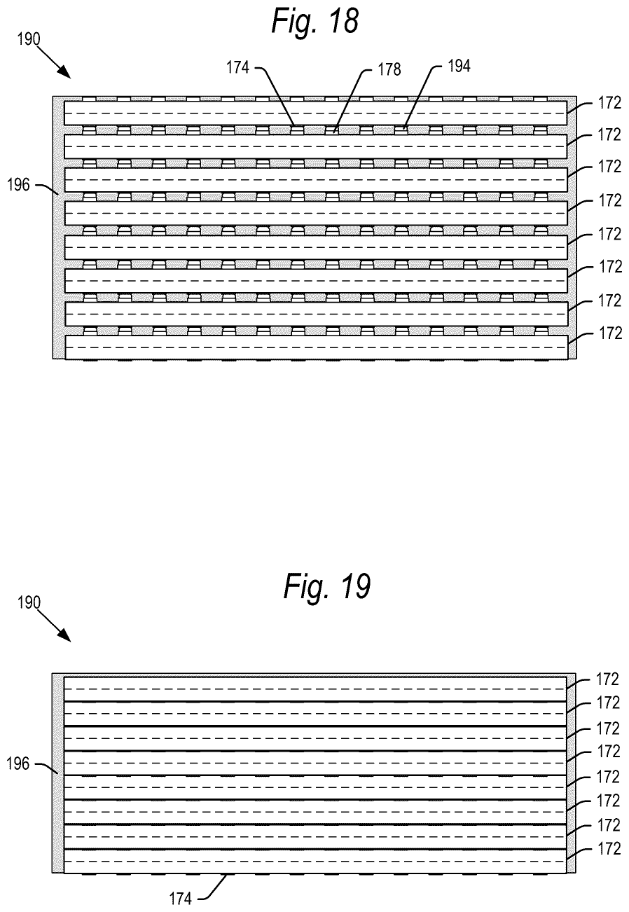

FIG. 18 shows a NAND stack 190 comprised of eight paired CBA memory dies 172. In stacking the paired CBA memory dies 172, the bond pads 174 on the bottom of each die 172 may be electrically coupled to the bump pad 178 on the next lower die by a micro bump, or solder bump, 194. The NAND stack 190 of FIG. 18 may be encapsulated in a mold compound 196 which encases the NAND stack 190 as well as extends between each of the CBA memory dies 172 as shown.

FIG. 19 shows a further embodiment of NAND stack 190 comprised of eight paired CBA memory dies 172. In the embodiment of FIG. 19, each CBA memory die 172 may include bond pads 174 on a top and bottom surface of the CBA memory die that are coplanar with the top and bottom surface of the CBA memory die. In this embodiment, the CBA memory dies 172 may be bonded to each other by Cu-to-Cu bonding and/or hybrid bonding so that there is substantially no space between adjacent CBA memory dies. The NAND stack 190 of FIG. 19 may be encapsulated in a mold compound 196 which encases the NAND stack 190 as shown.

The NAND stacks 190 of FIGS. 18 and 19 allow the high speed signal transfer through each of the dies (using the internal vias and pads within each paired CBA memory die) that is typically of HBMs. The NAND stacks 190 may be positioned on a PCB near a specialized (or other type) of processor to provide high bandwidth, high capacity storage to the processor. While the NAND stacks 190 of FIGS. 18 and 19 are shown as including eight paired CBA memory dies 172, it is understood that NAND stacks 190 may include other numbers of paired CBA memory dies 172 in further embodiments.

The Cu-to-Cu and/or hybrid bonded NAND stack 190 of FIG. 19 provides some additional advantages. For example, omitting the bumps 194 and bonding the CBA memory dies 172 directly to each other lowers the overall height of the NAND stack 190, compared to for example the NAND stack of FIG. 18. Moreover, in some embodiments, the mold compound between the CBM memory dies in FIG. 18 can act as a thermal barrier to heat conduction. Thus, as the CBA memory dies 172 of FIG. 19 are bonded directly against each other, heat is more easily conducted between the dies 172 and out of the NAND stack 190.

As a further advantage, a large number of CBA memory dies 172 may be stacked together. In particular, as noted above, individual conventional memory dies are prone to warpage and high stresses. The warpage and high stresses in conventional dies result in peeling of the dies at the edges when larger numbers of dies are stacked, especially in the NAND stack 190 of FIG. 19 where the dies are bonded directly together. However, as the CBA memory dies 172 are flat and have low stresses, large numbers (e.g., eight, sixteen, thirty-two, etc.) of such dies 172 may be stacked without peeling, even in the NAND stack of FIG. 19 where the dies are bonded directly together.

In embodiments described above, the paired CBA memory dies 172 are each comprised of a pair of non-volatile CBA memory dies. In further embodiments, instead of non-volatile memory dies, a paired memory die may be formed of volatile memory dies, including for example DRAM and SRAM. Such paired volatile memory dies may each comprise first and second volatile memory dies mounted to each other face-to-face as described above. Such paired volatile memory dies may be stacked as shown in FIGS. 18 and 19 to provide an HBM with high storage capacity and very high bandwidth.

In embodiments described above, the CBA wafers 158 were formed with a memory array wafer 100, thinned to its final thickness, and CMOS logic circuit wafer 110 that was left at its full thickness. These CBA wafers 158 may be shipped in that state for joining of the memory array wafers and further processing as described above. In further embodiments, the CBA wafers 158 may be formed with a memory array wafer 100, left at its full thickness, and CMOS logic circuit wafer 110 that thinned to its final thickness. These CBA wafers may be shipped in that state. Once at the die assembly fab, the wafers may be joined so that the CMOS logic circuit wafers 112 face each other face-to-face. Thereafter, the memory array wafers of each CBA wafer may be thinned and processed as described above.

In summary, one example of the present technology relates to a high bandwidth memory, comprising: a plurality of paired CMOS bonded array (CBA) memory dies, each paired CBA memory die of the plurality of paired CBA memory dies comprising: a first CBA memory die, comprising: a first semiconductor die, comprising: a first memory array formed in a first face of the first semiconductor die, the first memory array having a first coefficient of thermal expansion, a first substrate next to the first memory array and having a second coefficient of thermal expansion, a first group of bump pads formed in the first face of the first semiconductor die, and a second semiconductor die, comprising: a first CMOS logic circuit formed in the second semiconductor die, a second substrate next to the first CMOS logic circuit, a second group of bump pads; and a second CBA memory die, comprising: a third semiconductor die, comprising: a second memory array formed in a second face of the second semiconductor die, the second memory array having a third coefficient of thermal expansion, a third substrate next to the second memory array and having a fourth coefficient of thermal expansion, a third group of bump pads formed in the second face of the second semiconductor die, and a fourth semiconductor die, comprising: a second CMOS logic circuit formed in the fourth semiconductor die, a fourth substrate next to the first CMOS logic circuit, and a fourth group of bump pads; wherein the paired CBA memory die is configured to avoid warping by bonding the first and second CBA memory dies together first face to second face so that the first and third coefficients of thermal expansion balance each other out.

In another example, the present technology relates to a paired CMOS bonded array (CBA) memory die, comprising: a first CBA memory die, comprising: a first major surface, a first group of bump pads formed in the first major surface, a first semiconductor die, comprising: a first memory array having a first coefficient of thermal expansion, a first substrate next to the first memory array and having a second coefficient of thermal expansion, and a second semiconductor die, comprising: a first CMOS logic circuit having a third coefficient of thermal expansion, a second substrate next to the first CMOS logic circuit and having a fourth coefficient of thermal expansion, and a first set of electrical connections within the first and second semiconductor dies electrically coupled to the first group of bump pads in the first major surface; and a second CBA memory die, comprising: a second major surface, a second group of bump pads formed in the second major surface, a third semiconductor die, comprising: a second memory array having a fifth coefficient of thermal expansion, a third substrate next to the second memory array and having a sixth coefficient of thermal expansion, and a second semiconductor die, comprising: a second CMOS logic circuit having a seventh coefficient of thermal expansion, a fourth substrate next to the second CMOS logic circuit and having an eighth coefficient of thermal expansion, and a second set of electrical connections within the third and fourth semiconductor dies electrically coupled to the second group of bump pads in the second major surface; wherein the paired CBA memory die is configured to avoid warping by bonding the first and second CBA memory dies together first major surface to second major surface so that the coefficients of thermal expansion in the first and second CBA memory dies balance each other out.

In a further example, the present technology relates to A high bandwidth memory, comprising: a plurality of paired non-volatile memory dies, each paired non-volatile memory die of the plurality of paired non-volatile memory dies comprising: a first semiconductor die, comprising: a first non-volatile memory formed in a first face of the first semiconductor die, the first non-volatile memory having a first coefficient of thermal expansion, a first substrate next to the first non-volatile memory and having a second coefficient of thermal expansion, a first group of bump pads formed in the first face of the first semiconductor die, and a second semiconductor die, comprising: a second non-volatile memory formed in a second face of the second semiconductor die, the second non-volatile memory having a third coefficient of thermal expansion, a second substrate next to the second non-volatile memory and having a fourth coefficient of thermal expansion, a second group of bump pads formed in the second face of the second semiconductor die; wherein the paired non-volatile memory die is configured to avoid warping by bonding the first and second non-volatile memory dies together first face to second face so that the coefficients of thermal expansion in the first and second non-volatile memory dies balance each other out.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. A high bandwidth memory, comprising:
a plurality of paired CMOS bonded array (CBA) memory dies, each paired CBA memory die of the plurality of paired CBA memory dies comprising:
a first CBA memory die, comprising:
a first semiconductor die, comprising:
a first memory array formed in a first face of the first semiconductor die, the first memory array having a first coefficient of thermal expansion,
a first substrate next to the first memory array and having a second coefficient of thermal expansion,
a first group of bump pads formed in the first face of the first semiconductor die, and
a second semiconductor die, comprising:
a first CMOS logic circuit formed in the second semiconductor die,
a second substrate next to the first CMOS logic circuit,
a second group of bump pads; and
a second CBA memory die, comprising:
a third semiconductor die, comprising:
a second memory array formed in a second face of the second semiconductor die, the second memory array having a third coefficient of thermal expansion,
a third substrate next to the second memory array and having a fourth coefficient of thermal expansion,
a third group of bump pads formed in the second face of the second semiconductor die, and
a fourth semiconductor die, comprising:
a second CMOS logic circuit formed in the fourth semiconductor die,
a fourth substrate next to the first CMOS logic circuit, and
a fourth group of bump pads;
wherein the paired CBA memory die is configured to avoid warping by bonding the first and second CBA memory dies together first face to second face so that the first and third coefficients of thermal expansion balance each other out.

2. The high bandwidth memory of claim 1, wherein the first and second CBA memory dies are bonded to each other face-to-face by coupling the first and second groups of bump pads to each other.

3. The high bandwidth memory of claim 1, wherein the first CBA memory die comprises a first set of electrical connections extending between major planar surfaces of the first CBA memory die, the first set of electrical connections comprising the first and second groups of bump pads.

4. The high bandwidth memory of claim 3, wherein the first set of electrical connections further comprises a plurality of vias connected between the first and second groups of bump pads.

5. The high bandwidth memory of claim 3, wherein the second CBA memory die comprises a second set of electrical connections extending between major planar surfaces of the second CBA memory die, the second set of electrical connections comprising the third and fourth groups of bump pads.

6. The high bandwidth memory of claim 5, wherein the second set of electrical connections further comprises a plurality of vias connected between the third and fourth groups of bump pads.

7. The high bandwidth memory of claim 1, wherein the paired CBA memory die is further configured to avoid warping by bonding the first and second CBA memory dies together first face to second face so that the second and fourth coefficients of thermal expansion of the first and third substrates balance each other out.

8. The high bandwidth memory of claim 1, wherein the first CMOS logic circuit comprises a fifth coefficient of thermal expansion and the second CMOS logic circuit comprises a sixth coefficient of thermal expansion, wherein the paired CBA memory die is further configured to avoid warping by bonding the first and second CBA memory dies together first face to second face so that the fifth and sixth coefficients of thermal expansion balance each other out.

9. The high bandwidth memory of claim 1, wherein the second substrate comprises a seventh coefficient of thermal expansion and the fourth substrate comprises an eighth coefficient of thermal expansion, wherein the paired CBA memory die is further configured to avoid warping by bonding the first and second CBA memory dies together first face to second face so that the seventh and eighth coefficients of thermal expansion balance each other out.

10. The high bandwidth memory of claim 1, wherein the plurality of paired CBA memory dies comprises eight paired CBA memory dies for a total of sixteen CBA memory dies.

11. A paired CMOS bonded array (CBA) memory die, comprising:
a first CBA memory die, comprising:
a first major surface,
a first group of bump pads formed in the first major surface,
a first semiconductor die, comprising:
a first memory array having a first coefficient of thermal expansion,
a first substrate next to the first memory array and having a second coefficient of thermal expansion, and
a second semiconductor die, comprising:
a first CMOS logic circuit having a third coefficient of thermal expansion,
a second substrate next to the first CMOS logic circuit and having a fourth coefficient of thermal expansion, and
a first set of electrical connections within the first and second semiconductor dies electrically coupled to the first group of bump pads in the first major surface;
and
a second CBA memory die, comprising:
a second major surface,
a second group of bump pads formed in the second major surface,
a third semiconductor die, comprising:
a second memory array having a fifth coefficient of thermal expansion,
a third substrate next to the second memory array and having a sixth coefficient of thermal expansion, and
a second semiconductor die, comprising:
a second CMOS logic circuit having a seventh coefficient of thermal expansion,
a fourth substrate next to the second CMOS logic circuit and having an eighth coefficient of thermal expansion, and
a second set of electrical connections within the third and fourth semiconductor dies electrically coupled to the second group of bump pads in the second major surface;
wherein the paired CBA memory die is configured to avoid warping by bonding the first and second CBA memory dies together first major surface to second major surface so that the coefficients of thermal expansion in the first and second CBA memory dies balance each other out.

12. The paired CBA memory die of claim 11, wherein the first major surface is formed in the first semiconductor die, and the second major surface is formed in the third semiconductor die.

13. The paired CBA memory die of claim 12, wherein the first set of electrical connections electrically couple the first memory array to the first group of bump pads, and the first set of electrical connections electrically couple the first CMOS logic circuits to the first group of bump pads through the first semiconductor die.

14. The paired CBA memory die of claim 12, wherein the second set of electrical connections electrically couple the second memory array to the second group of bump pads, and the second set of electrical connections electrically couple the second CMOS logic circuits to the second group of bump pads through the third semiconductor die.

15. The paired CBA memory die of claim 11, wherein the first major surface is formed in the second semiconductor die, and the second major surface is formed in the fourth semiconductor die.

16. The paired CBA memory die of claim 15, wherein the first set of electrical connections electrically couple the first CMOS logic circuits to the first group of bump pads, and the first set of electrical connections electrically couple the first memory array to the first group of bump pads through the second semiconductor die.

17. The paired CBA memory die of claim 15, wherein the second set of electrical connections electrically couple the second CMOS logic circuits to the second group of bump pads, and the second set of electrical connections electrically couple the second memory array to the second group of bump pads through the fourth semiconductor die.

18. The paired CBA memory die of claim 11, wherein the first set of electrical connections comprise a first set of vias physically connected to the first group of bump pads at the first surface.

19. A NAND stack, comprising:
a plurality of paired non-volatile memory dies, each paired non-volatile memory die of the plurality of paired non-volatile memory dies comprising:
a first semiconductor die, comprising:
a first non-volatile memory formed in a first face of the first semiconductor die, the first non-volatile memory having a first coefficient of thermal expansion,
a first substrate next to the first non-volatile memory and having a second coefficient of thermal expansion,
a first group of bump pads formed in the first face of the first semiconductor die, and
a second semiconductor die, comprising:
a second non-volatile memory formed in a second face of the second semiconductor die, the second non-volatile memory having a third coefficient of thermal expansion,
a second substrate next to the second non-volatile memory and having a fourth coefficient of thermal expansion,
a second group of bump pads formed in the second face of the second semiconductor die;
wherein the paired non-volatile memory die is configured to avoid warping by bonding the first and second non-volatile memory dies together first face to second face so that the coefficients of thermal expansion in the first and second non-volatile memory dies balance each other out.

20. The HBM of claim 19, wherein the plurality of paired non-volatile memory dies are bonded directly to each other using hybrid bonding.
